(19) United States
(12) Patent Application Publication
(10) Pub. No.: US 2010/0302856 A1
(43) Pub. Date: Dec. 2, 2010

(54) NONVOLATILE MEMORY DEVICE AND METHOD OF PROGRAMMING AND READING THE SAME

(76) Inventor: Sung Hoon AHN, Gyeonggi-do (KR)

Correspondence Address: IP & T GROUP LLP, 7700 Little River Turnpike, Suite 207, Annandale, VA, 22003, US

(21) Appl. No.: 12/788,672

(22) Filed: May 27, 2010

(30) Foreign Application Priority Data
May 29, 2009 (KR) 10-2009-0047835
May 24, 2010 (KR) 10-2010-0048109

(51) Int. Cl. G11C 16/04; G11C 7/10

(52) U.S. Cl. 365/185.18; 365/189.05

(57) ABSTRACT

A nonvolatile memory device includes a control circuit configured to generate a control signal by counting a number of first data among input data, a buffer unit configured to temporarily store the input data, invert the input data in response to the control signal, and store the inverted data or the input data as the program data, and a memory cell block configured to receive and store the program data.

### CROSS-REFERENCE TO RELATED APPLICATION

Priority to Korean patent application number 10-2009-0047835 filed on May 29, 2009 and Priority to Korean patent application number 10-2010-0048109 filed on May 24, 2010, the entire disclosure of which are incorporated by reference herein, are claimed.

### BACKGROUND

Exemplary embodiments relate to a nonvolatile memory device and a method of programming and reading the same and, more particularly, to a nonvolatile memory device, which is capable of reducing current consumption of a program operation by inverting a value of program data, and a method of programming and reading the same.

Recently, there is an increasing demand for nonvolatile memory devices which can be electrically programmed and erased and which do not require the refresh function of rewriting data at specific intervals.

A nonvolatile memory cell of a nonvolatile memory device is an element in which electrical program and erase operations of data can be performed. The program and erase operations are performed in such a manner that electrons stored in a thin oxide layer of the cell are moved by a strong electric field applied to the oxide layer, so that a threshold voltage of the cell is shifted.

In a nonvolatile memory device, such as a NAND type flash memory device, the program and read operations are performed on each page, including a number of memory cells. That is, during the program operation, input data are programmed into the memory cells of a corresponding page at the same time. During the read operation, data stored in the memory cells of a corresponding page are read at the same time.

With a gradual increase in the capacity of the NAND type flash memory device, the number of memory cells belonging to one page is gradually increased. Accordingly, there may be an increase in the number of cells to be programmed (i.e., program cells), and therefore, more program cells may be programmed at the same time. Further, as the number of memory cells being programmed at the same time increases, current consumption also increases.

### BRIEF SUMMARY

Exemplary embodiments relate to a nonvolatile memory device and a method of programming and reading the same, which are capable of reducing the number of program cells by counting the number of first data among input data and programming the first data as second data when the number of the first data is more than half the total amount of input data. The nonvolatile memory device and the method of programming and reading the same can reduce current consumption and back-pattern dependency effects of the memory device, and also improve a distribution of threshold voltages of cells.

A nonvolatile memory device according to an aspect of the present disclosure includes a control circuit configured to generate a control signal by counting a number of first data among input data, a buffer unit configured to invert or maintain the input data in response to the control signal and to store the inverted data or the maintained data as program data, and a memory cell block configured to store the program data.

A method of programming a nonvolatile memory device according to another aspect of the present disclosure includes counting a number of first data among input data, inverting the input data and storing the inverted data as program data, if the number of first data is greater than a specific amount as a result of the counting, storing the input data as the program data, if the number of first data is equal to or less than the specific amount, storing inverse information about the input data, and storing the program data and the inverse information in main cells and a flag cell, respectively.

In accordance with yet another aspect of the present disclosure, there is provided a method of reading a nonvolatile memory device, comprising main cells for storing program data and a flag cell for storing program operation information. The method includes reading the program operation information by performing a first read operation, reading the program data by performing a second read operation and storing the read program data, retaining or inverting the stored program data on the basis of the program operation information and storing resulting data as read data, and outputting the read data.

In accordance with still yet another aspect of the present disclosure, there is provided a nonvolatile memory device including a control circuit configured to generate a control signal by counting a number of first data among input data, and a buffer unit configured to selectively invert the input data in response to the control signal and store the selectively inverted data as program data.

### BRIEF DESCRIPTION OF THE DRAWINGS

FIG. 1 is a block diagram of a nonvolatile memory device according to an embodiment of this disclosure;

FIG. 2 is a block diagram of a memory cell block and a buffer unit according to an embodiment of this disclosure;

FIG. 3 is a flowchart illustrating a method of programming a nonvolatile memory device according to an embodiment of this disclosure;

FIGS. 4A and 4B are diagrams illustrating an operation of inverting input data according to an embodiment of this disclosure; and

FIG. 5 is a flowchart illustrating a method of reading a nonvolatile memory device according to an embodiment of this disclosure.

### DESCRIPTION OF EMBODIMENTS

Hereinafter, exemplary embodiments of the present disclosure will be described in detail with reference to the accompanying drawings. The figures are provided to facilitate understanding the exemplary embodiments of the disclosure by those of ordinary skill in the art.

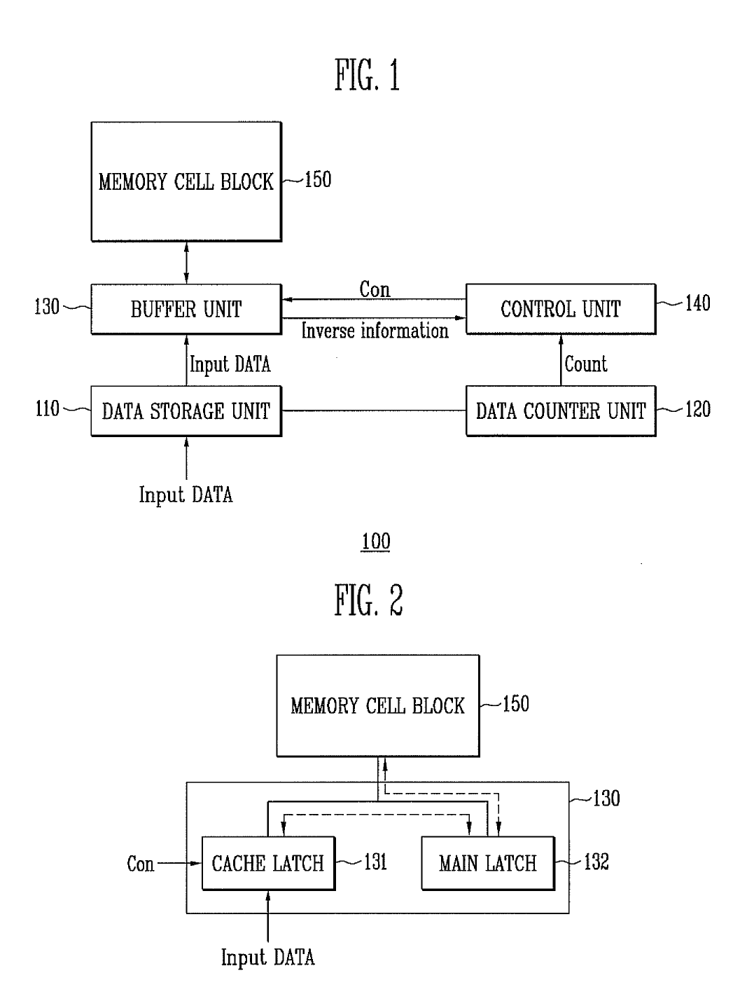

FIG. 1 is a block diagram of a nonvolatile memory device according to an embodiment of this disclosure.

Referring to FIG. 1, the nonvolatile memory device 100 includes a data storage unit 110, a data counter unit 120, a buffer unit 130, a control unit 140, and a memory cell block 150.

The data storage unit 110 stores external input data Input DATA.

The data counter unit 120 counts the number of first data (e.g., data ‘0 ’) among the input data stored in the data storage unit 110, and outputs a count signal Count based on the number of first data counted.

The buffer unit 130 temporarily stores the input data Input DATA stored in the data storage unit 110. A nonvolatile memory device may use a page buffer as the buffer unit 130.

The control unit 140, responding to the count signal Count, compares a specific/certain amount with the number of first data counted and outputs a control signal Con according to a result of the comparison. The buffer unit 130 retains or inverts the input data Input DATA in response to the control signal Con and stores resulting data as program data.

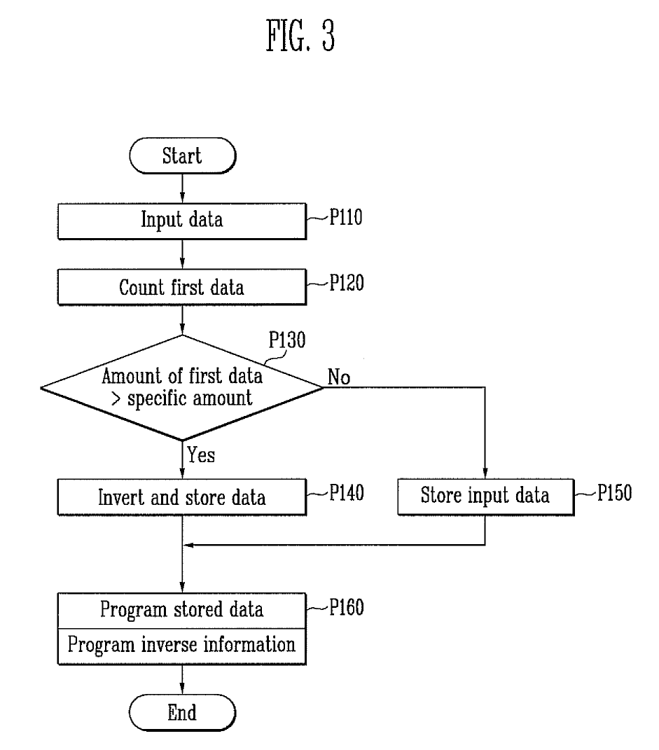

FIG. 2 is a block diagram of the memory cell block 150 and the buffer unit 130 according to an embodiment of this disclosure.

Referring to FIG. 2, the buffer unit 130 includes a cache latch 131 and a main latch 132. During a program operation, the buffer unit 130 stores the input data Input DATA in the cache latch 131, inverts or retains the input data Input DATA in response to the control signal Con, and stores the resulting data in the main latch 132 as the program data. The program data stored in the main latch 132 is sent to the memory cell block.

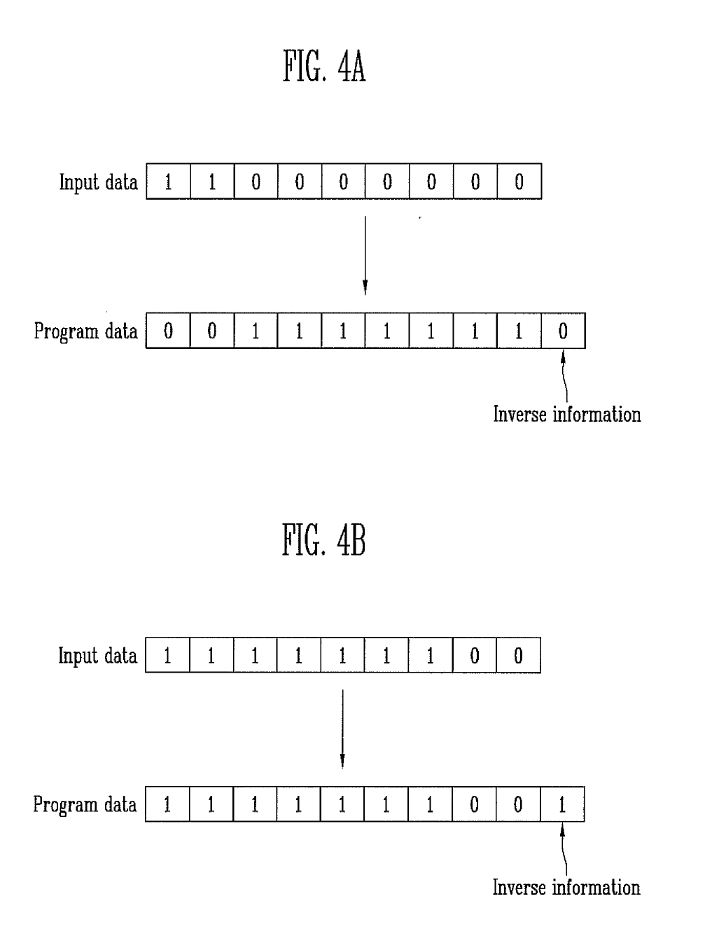

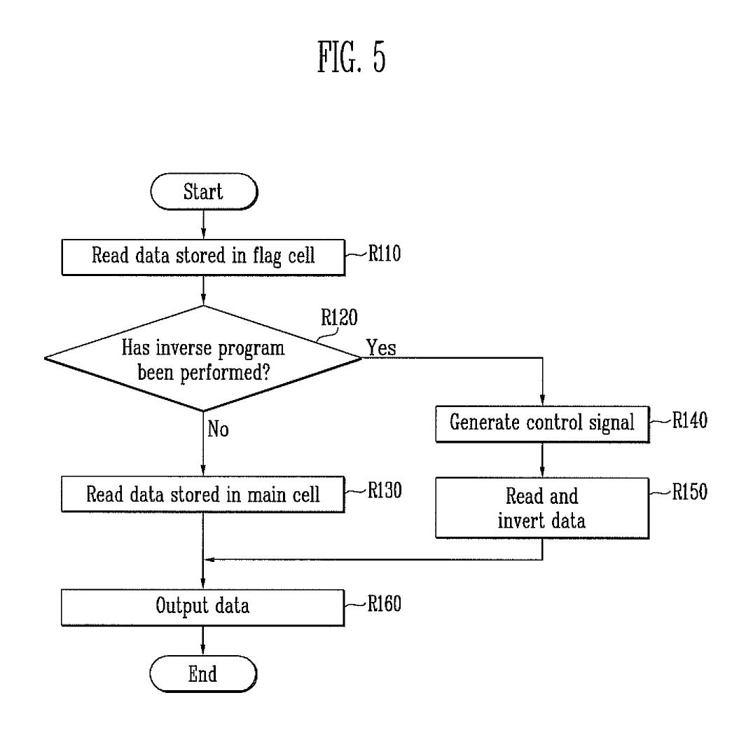

FIG. 3 is a flowchart illustrating a method of programming the nonvolatile memory device according to an embodiment of this disclosure. FIGS. 4A and 4B are diagrams illustrating an operation of inverting input data according to an embodiment of this disclosure.

The method of programming the nonvolatile memory device according to the embodiment of this disclosure is described below with reference to FIGS. 1 to 3, 4A, and 4B.

First, external input data are received and stored in the data storage unit 110 at step P110. Furthermore, the buffer unit 130 temporarily stores the input data stored in the data storage unit 110.

The data counter unit 120 counts the number of first data (e.g., data ‘0’) among the input data stored in the data storage unit 110 and outputs the count signal Count based on the number of first data counted at step P120.

The control unit 140 determines whether the number of first data counted is greater than a specific amount at step P130. The specific amount is preferably half the number of memory cells belonging to one page of the memory cell block 150 or equal to the number of second data (e.g. data ‘1 ’ where the first data is data ‘0 ’) among the input data. The control unit 140 outputs the control signal Con according to a result of the determination.

If, as a result of the determination, the number of first data counted is determined to be greater than the specific amount, the buffer unit 130 inverts the input data stored therein in response to the control signal Con, as shown in FIG. 4A and stores the inverted data as program data at step P140. Accordingly, the number of second data included in the program data is greater than the number of first data included in the program data. Here, information about whether the inverse operation has been performed is stored in a flag cell of the memory cell block 150 as inverse information.

If, as a result of the determination at step P130, the number of first data is determined to be equal to or less than the specific amount, the buffer unit 130 retains the input data stored therein in response to the control signal Con, as shown in FIG. 4B, and stores the input data as program data at step P150. Accordingly, the number of second data included in the program data is greater than the number of first data. Here, information about whether the inverse operation has been performed is stored in the flag cell of the memory cell block 150 as inverse information.

Here, the buffer unit 130 performs the inverse operation in response to the control signal Con as follows. As described above with reference to FIG. 2, the input data stored in the cache latch 131 are retained or inverted in response to the activation or inactivation of the control signal Con and then sent to the main latch 132. The program data stored in the main latch 132 are programmed into memory cells.

The program data stored in the buffer unit 130 are sent to the memory cell block 150. When a program voltage is supplied to a word line corresponding to a selected page of the memory cell block, the program data are programmed into memory cells and a flag cell belonging to the corresponding page at step P160.

When a program operation is performed, the number of first data on which the program operation is substantially performed is always less than the number of second data. Accordingly, the current consumption caused by the program operation can be reduced.

FIG. 5 is a flowchart illustrating a method of reading a nonvolatile memory device according to an embodiment of this disclosure.

The method of reading the nonvolatile memory device according to the embodiment of this disclosure is described below with reference to FIGS. 1, 2, and 5.

First, inverse information stored in the flag cell of the memory cell block 150 is read and stored in the buffer unit 130 at step R110.

It is then determined whether program data programmed into the main cells of the memory cell block 150 have been inverted during a program operation on the basis of the inverse information at step R120.

If, as a result of the determination, the program data are determined not to have been inverted during the program operation, the program data programmed into the main cells of the memory cell block 150 are read and stored in the buffer unit 130 at step R130. Here, the program data programmed into the main cells of the memory cell block 150 are stored in the main latch 132 of the buffer unit 130 through bit lines coupled to the memory cells and then stored in the cache latch 131.

If, as a result of the determination at step R120, the program data are determined to have been inverted during the program operation, the control unit 140 generates the control signal Con at step R140.

The buffer unit 130 reads the program data, inverts the program data in response to the control signal Con, and stores inverted program data at step R150. Here, the program data are first stored in the main latch 132 through the bit lines coupled to the main cells of the memory cell block 150, and then inverted and stored in the cache latch 131 in response to the control signal Con.

Next, the program data stored in the buffer unit 130 are externally outputted at step R160.

In accordance with exemplary embodiments of this document, the number of first data among input data is counted and if, as a result of the count, the number of first data is more than half the total amount of input data, the first data is programmed as second data. Accordingly, the number of program cells (i.e., the cells required to be programmed), current consumption, and the back-pattern dependency effects of a memory device can be reduced. Furthermore, a distribution of threshold voltages of cells can be improved.

What is claimed is:

1. A nonvolatile memory device, comprising:
a control circuit configured to generate a control signal by counting a number of first data among input data and;
a buffer unit configured to invert or maintain the input data in response to the control signal and to store the inverted data or the maintained data as program data; and
a memory cell block configured to store the program data.

2. The nonvolatile memory device of claim 1, wherein the control circuit comprises:
a data counter configured to count the number of first data and output a count signal based on the number of first data counted; and
a controller configured to compare a specific amount with the count signal to generate the control signal.

3. The nonvolatile memory device of claim 1, wherein the buffer unit comprises:
a cache latch configured to temporarily store the input data; and
a main latch configured to invert the input data, stored in the cache latch, in response to the control signal, store the inverted data as the program data, and send the program data to the memory cell block.

4. A method of programming a nonvolatile memory device, the method comprising:
counting a number of first data among input data;
inverting the input data and storing the inverted data as program data, if the number of first data is greater than a specific amount as a result of the counting;
storing the input data as the program data, if the number of first data is equal to or less than the specific amount;
storing inverse information about the input data; and
storing the program data and the inverse information in main cells and a flag cell, respectively.

5. The method of claim 4, wherein the input data are programmed into memory cells belonging to a same page.

6. The method of claim 4, wherein the first data is data ‘0’, which corresponds to a program cell.

7. The method of claim 4, wherein the specific amount is half of a number of memory cells belonging to a same page.

8. The method of claim 4, wherein inverting the input data and storing the inverted data as program data includes:
inverting the first data to a level of second data;
inverting the second data to a level of the first data; and
storing the inverted data as the program data.

9. The method of claim 8, wherein a number of the program data having the level of the first data is less than a number of the program data having the level of the second data.

10. A method of reading a nonvolatile memory device, comprising main cells for storing program data and a flag cell for storing program operation information, the method comprising:
reading the program operation information by performing a first read operation;
reading the program data by performing a second read operation and storing the read program data;
retaining or inverting the stored program data on a basis of the program operation information and storing resulting data as read data; and
outputting the read data.

11. The method of claim 10, wherein retaining or inverting the stored program data and storing the resulting data as the read data includes:
storing the stored program data as the read data, if the program operation information is normal program operation information, and
inverting the stored program data and storing the inverted program data as the read data, if the program operation information is inverse program operation information.

12. A nonvolatile memory device, comprising:
a control circuit configured to generate a control signal by counting a number of first data among input data; and
a buffer unit configured to selectively invert the input data in response to the control signal and store the selectively inverted data as program data.

13. The nonvolatile memory device of claim 12, further comprising a memory cell block configured to store the program data or output the stored program data.

14. The nonvolatile memory device of claim 13, wherein the control circuit is configured to generate the control signal in response to inverse information of the stored program data.

15. The nonvolatile memory device of claim 14, wherein the buffer unit is configured to selectively invert the stored program data outputted from the memory cell block according to the control signal and output the selectively inverted program data.

16. The nonvolatile memory device of claim 12, wherein the control circuit comprises:
a data counter configured to count the number of first data and output a count signal based on the number of first data counted; and
a controller configured to compare a specific amount with the count signal to generate the control signal.

17. The nonvolatile memory device of claim 16, wherein the buffer unit is configured to invert the input data if the number of the first data is greater than the specific amount.

18. The nonvolatile memory device of claim 16, wherein the buffer unit is configured to store information on whether the input data are inverted as inverse information of the program data.
